(19) United States
(12) Patent Application Publication
(10) Pub. No.: US 2014/0373349 A1
(43) Pub. Date: Dec. 25, 2014

(54) LASER DIODE PATTERNING OF TRANSPARENT CONDUCTIVE FILMS

(71) Applicant: Carestream Health, Inc., Rochester, NY (US)

(72) Inventors: David R. Whitcomb, Woodbury, MN (US); Robert R. Brearey, Oakdale, MN (US); Stephen P. Riehm, Stillwater, MN (US)

(21) Appl. No.: 14/290,212

(22) Filed: May 29, 2014

Related U.S. Application Data
(60) Provisional application No. 61/837,217, filed on Jun. 20, 2013.

(51) Int. Cl. G06F 3/045

(52) U.S. Cl. CPC G06F 3/045
USPC 29/846

(57) ABSTRACT

Methods of patterning metal nanowire containing transparent conductive films using laser diodes, where the films comprise a radiation absorbing substance, such as an infrared absorbing substance or an ultraviolet absorbing substance. The use of laser diodes can decrease the time and costs associated with patterning transparent conductive films comprising nanowires, such as silver nanowires.

### CROSS REFERENCE TO RELATED APPLICATIONS

This application claims the benefit of U.S. Provisional Application No. 61/837,217, filed Jun. 20, 2013, entitled “LASER DIODE PATTERNING OF TRANSPARENT CONDUCTIVE FILMS,” which is hereby incorporated by reference in its entirety.

### BACKGROUND

Transparent conductive films are used in electronic applications such as touch screen sensors for portable electronic devices. Transparent conductive films comprising silver nanowires are particularly well suited for such applications because of their flexibility, high conductivity, and high optical transparency.

For many electronic applications, such transparent conductive films are patterned in order to provide low resistivity regions separated by high resistivity regions. For commercial applications, the transparent conductor must have a patterned conductivity that can be produced in a low-cost, high-throughput process.

### SUMMARY

A laser diode can be used to pattern transparent conductive films comprising nanowires to form regions of high resistivity. We have discovered methods to enhance the ability of the nanowires in the transparent conductive film to capture the radiation energy from a laser diode. Such methods lead to a low cost, high throughput patterning process.

At least some embodiments provide methods for patterning a transparent conductive film comprising providing a transparent conductive film comprising a first region exhibiting a first resistivity, the first region comprising a metal nanowire and a radiation absorbing substance; and irradiating the transparent conductive film with a radiation source, wherein, after irradiation of the transparent conductive film, the first region exhibits a second resistivity that is higher than the first resistivity. In some embodiments, the metal nanowire may comprise silver nanowire. In some embodiments, the first region may comprise a plurality of metal nanowires. In some embodiments, the radiation source is a continuous wave laser, such as a diode or a laser diode.

In any of the above embodiments, the irradiating may comprise irradiating the first region, and the transparent conductive film may further comprise a second region exhibiting a third resistivity that is less than the second resistivity.

In any of the above embodiments, the radiation absorbing substance may comprise an infrared absorbing substance. In any of the above embodiments, the radiation absorbing substance may comprise an ultraviolet absorbing substance. In any of the above embodiments, the radiation absorbing substance may comprise a bonding component, such as a ligand. In any of the above embodiments, the radiation absorbing substance may comprise a dye.

In any of the above embodiments, the radiation absorbing substance may comprise an infrared absorbing substance exhibiting one or more absorption peaks having a maximum at a wavelength (λₘₐₓ) from between about 0.7 to 1000 p.m. In any of the above embodiments, the radiation absorbing substance may comprise 1,1′,3,3,3′,3′-hexamethylindotricarbocyanine iodide. In any of the above embodiments, the radiation absorbing substance may comprise 3,3′-diethylthiatricarbocyanine perchlorate. In any of the above embodiments, the radiation absorbing substance may comprise cyclobutenediylium, 1,3-bis[2,3-dihydro-2,2-bis[[(1-oxohexyl)oxy]methyl]-1H-perimidin-6-yl]-2,4-dihydroxy-bis(inner salt). In any of the above embodiments, the radiation absorbing substance may comprise 4-[2-[2-chloro-3-[(2,6-diphenyl-4H-thiopyran-4-ylidene)ethylidene]-1-cyclohexen-1-yl]ethenyl]-2,6-diphenylthiopyrylium tetrafluoroborate. In any of the above embodiments, the radiation absorbing substance may comprise 6-chlor-2-[2-[3-[(6-chlor-1-ethyl-2H-benzo[cd]indol-2-yliden)-ethylidene]-2-phenyl-1-cyclopenten-1-yl]-ethenyl]-1-ethyl-benzo[cd]indolium tetrafluoroborate. In any of the above embodiments, the radiation absorbing substance may impart no color that is visible to the unaided eye.

In some embodiments, a patterning kit may comprise a transparent conductive film comprising a silver nanowire and a radiation absorbing substance, the radiation absorbing substance exhibiting an absorption peak at a wavelength; and, a diode configured to irradiate the transparent conductive film at the wavelength. In some embodiments, the transparent conductive film comprises a plurality of silver nanowires.

These embodiments and other variations and modifications may be better understood from the brief description of the drawings, description, exemplary embodiments, examples, claims, and drawings that follow. Any embodiments provided are given only by way of illustrative example. Other desirable objectives and advantages inherently achieved may occur or become apparent to those skilled in the art. The invention is defined by the appended claims.

### BRIEF DESCRIPTION OF THE DRAWINGS

FIG. 1 shows an embodiment of an apparatus for patterning a transparent conductive film using a translation stage.

FIG. 2 shows an embodiment of an apparatus for patterning a transparent conductive film using a drum.

### DESCRIPTION

All publications, patents, and patent documents referred to in this document are incorporated by reference herein in their entirety, as though individually incorporated by reference.

U.S. Provisional Application No. 61/837,217, filed Jun. 20, 2013, entitled “LASER DIODE PATTERNING OF TRANSPARENT CONDUCTIVE FILMS,” is hereby incorporated by reference in its entirety.

### Introduction

A method of patterning transparent conductive films comprises irradiating a transparent conductive film with a diode laser. Where such transparent conductive films comprise nanowires, we have discovered that incorporation of a radiation absorbing substance may facilitate the use of a diode, such as a laser diode, in patterning the films. The use of a laser diode can decrease the time and costs associated with patterning transparent conductive films comprising nanowires.

### Transparent Conductive Film

Transparent conductive films may comprise conductive microstructures or conductive nanostructures in one or more transparent conductive layers. Microstructures and nanostructures are defined according to the length of their shortest dimensions. The shortest dimension of the nanostructure is sized between 1 nm and 100 nm. The shortest dimension of the microstructure is sized between 0.1 μm to 100 μm. Conductive nanostructures may include, for example, metal nanostructures. In some embodiments, the conductive nanostructures may be metal nanowires, carbon nanotubes, metal meshes, transparent conductive oxide, and graphene. In some embodiments, the conductive nanostructures may be metal nanowires, such as, for example, silver nanowires. Examples of transparent conductive films comprising silver nanowires and methods for preparing them are disclosed in U.S. patent application publication 2012/0107600, entitled “TRANSPARENT CONDUCTIVE FILM COMPRISING CELLULOSE ESTERS,” which is hereby incorporated by reference in its entirety. The transparent conductive films may be patterned to introduce regions of higher resistivity within the transparent conductive film, leaving other regions as lower resistivity regions.

In some embodiments, the transparent conductive film may comprise a substrate upon which the one or more transparent conductive layers are disposed. The substrate may comprise a polymer, such as polyethylene terephthalate (PET). In some embodiments, one or more carrier layers, such as “interlayers” or “intermediate layers,” may be located between the transparent conductive layers and the substrate. The carrier layer may, in some cases, be an “adhesion promotion layer” that improves adhesion between the transparent conductive layers and substrate. The carrier layer may be applied onto the substrate by various methods, such as by coating. In some embodiments, the carrier layer is sequentially applied with the application of the transparent conductive layers. In some embodiments, the carrier layer is simultaneously applied with the application of the transparent conductive layer. In some embodiments, the carrier layer comprises a single-phase mixture of at least one polymer. In some embodiments, the carrier layer comprises a hard coat layer. In such a case, the hard coat layer may be abrasion resistant.

### Radiation Absorbing Substance

In some embodiments, a radiation absorbing substance is incorporated into a transparent conductive film. The radiation absorbing substance may absorb ionizing or non-ionizing radiation. In some embodiments, the radiation absorbing substance may absorb non-ionizing radiation, such as electromagnetic radiation. In such a case, the radiation absorbing substance may be an infrared absorbing substance that absorbs infrared radiation or an ultraviolet absorbing substance that absorbs ultraviolet radiation. The radiation absorbing substance may be in the form of a dye or a pigment. Dyes are liquids or compounds that are soluble in a vehicle, whereas pigments are insoluble solids that may be dispersed in a vehicle. Dyes may also have functional groups that are able to react with other chemical species.

In some embodiments, an infrared dye (“IR dyes”) is incorporated into a transparent conductive film. IR dyes may be any dye that provides suitable infrared absorption—that is, exhibiting one or more absorption peaks having a maximum at a wavelength (λₘₐₓ) from between about 0.7 to 1000 μm. Non-limiting examples of suitable infrared dyes include 1,1′,3,3,3′,3′-hexamethylindotricarbocyanine iodide, λₘₐₓ 740 nm; 3,3′-diethylthiatricarbocyanine perchlorate, λₘₐₓ 760 nm; cyclobutenediylium, 1,3-bis[2,3-dihydro-2,2-bis[[(1-oxohexyl)oxy]methyl]-1H-perimidin-6-yl]-2,4-dihydroxy-bis(inner salt), λₘₐₓ 799 nm; 4-[2-[2-chloro-3-[(2,6-diphenyl-4H-thiopyran-4-ylidene)ethylidene]-1-cyclohexen-1-yl]ethenyl]-2,6-diphenylthiopyrylium tetrafluoroborate, available through Sigma-Aldrich Co. LLC. as Aldrich IR-1061, λₘₐₓ 1061 nm; 6-chlor-2-[2-[3-[(6-chlor-1-ethyl-2H-benzo[cd]indol-2-yliden)-ethylidene]-2-phenyl-1-cyclopenten-1-yl]-ethenyl]-1-ethyl-benzo[cd]indolium tetrafluoroborate, available through Sigma-Aldrich Co. LLC as Aldrich IR-1051, λₘₐₓ 1051 nm.

Ultraviolet dyes (“UV dyes) may be any dye that provides suitable ultraviolet absorption—that is, exhibiting one or more absorption peaks having a maximum at a wavelength (λₘₐₓ) from between about 0.4 to 0.01 μm. Non-limiting examples of UV dyes includes 2,6-diphenyl-4-(2,4,6-triphenyl-1-pyridinio)phenolate, 2,6-diphenyl-4-(2,4,6-triphenylpyridinio)phenolate, available through Sigma-Aldrich Co. LLC as Reichardt's dye, λₘₐₓ 306 nm and λₘₐₓ 551 nm; and 5-[[4-[4-(2,2-diphenylethenyl)phenyl]-1,2,3-3a,4,8b-hexahydrocyclopent[b]indol-7-yl]methylene]-2-(3-ethyl-4-oxo-2-thioxo-5-thiazolidinylidene)-4-oxo-3-thiazolidineacetic acid, Indoline dye D149, Purple Dye, also available through Sigma-Aldrich Co. LLC as D149 dye, λₘₐₓ 531 nm.

In some embodiments, the dye exhibits little or no absorption in the visible region of the spectrum to maintain the transparency of the film. In such a case, no color is imparted to the film that may be detected by the unaided eye. In other embodiments, the dye exhibits absorption in the visible region of the spectrum to impart a color to the film. In such a case, the unaided eye may be able to detect color imparted to the film. In some embodiments, the dye may be bleachable so any color imparted to the film by the dye can be masked by bleaching.

In some embodiments, the radiation absorbing material may comprise a bonding component that can or has a tendency to combine with or bind to a metal atom or ion by chemical reaction to form a chemical compound. For example, the bonding component may be a ligand. In some embodiments, the bonding component, such as a ligand, can or has a tendency to combine with or bind to a silver atom or ion. Without wishing to be bound by theory, it is believed that a ligand that chemically binds the dye to the silver on the nanowire surface would more precisely locate absorption on the nanowire. In such a case, lower levels of such dye may be used to achieve the same level of heat absorption for increasing resistivity at desired positions on the film.

Various methods may be used to incorporate a dye into a transparent conductive film. In some embodiments, the dye and nanowire are in a single layer, such as, for example, a transparent conductive layer. In some cases, the dye and the nanowire are mixed into a composition from which a transparent conductive layer is formed. In other cases, the dye is coated onto the nanowire. In other embodiments, a layer comprising dye is coated onto the transparent conductive layer comprising the nanowire. Where a layer comprising dye is coated onto the transparent conductive layer, the dye may optionally be removed from the transparent conductive layer comprising the nanowire.

Patterning with a Diode Laser

The applicants do not intend the invention to be bound by any mechanism of operation. However, in order to appreciate the advantages of the invention, applicants offer the following insight. The radiation absorption properties of the nanostructure are determined by transverse and longitudinal surface plasmon resonances. The peak of the transverse absorption resonance remains relatively fixed in the visible portion of the spectrum with the positioning dictated by the type of metal and size of the nanostructure. The peak of the longitudinal absorption resonance shifts toward the infrared portion of the spectrum with the positioning dictated by the length of the nanostructure. A metal nanowire, such as a silver nanowire, may be highly reflective so absorption may be weak over the entire electromagnetic spectrum. However, a silver nanowire may be somewhat more absorptive of infrared radiation based on the unconstrained length of the nanowire. The incorporation of an infrared absorbing substance may further enhance the ability of the transparent conductive film comprising a silver nanowire to absorb infrared radiation.

In some embodiments, radiation from a radiation source is applied to the transparent conductive film comprising a radiation absorbing substance to produce regions of higher resistivity and create an electrical pattern in the transparent conductive film. In some embodiments, the radiation absorbing substance has an absorption peak at a laser wavelength in a region of the electromagnetic spectrum and the transparent conductive film is irradiated at the laser wavelength within that region.

The radiation absorbing substance may help focus the energy of the diode laser on the nanowires. Without wishing to be bound by theory, it is believed that radiation increases resistivity by disrupting the electrical connection between nanowires or electrical conductivity of the individual nanowire. Radiation may, in some cases, cause a change in resistivity by changing the relative positions of nanowires in the transparent conductive film, resulting in a decrease in number or quality of electrical connections between nanowires. Radiation absorption by a nanowire may, in other cases, also cause internal loss of conductivity of the nanowire or a change in phase of the nanowire.

In some embodiments, a radiation source, such as a lower energy laser, may be used to irradiate the transparent conductive film. An example of a lower energy laser includes a continuous wave laser. A continuous wave laser can lack the higher energy of a pulsed laser. Pulsed lasers can produce pulses of large energy. Since pulse energy is equal to the average power divided by the repetition rate, large amounts of energy can be produced by lowering the rate of pulses so more energy can be built up in between pulses. A nanowire in a film can be evaporated if heated in a very short time using, for example, a pulsed laser. A continuous wave laser, such as a laser diode, may supply energy gradually so that heat may be absorbed into the bulk of the film or conducted away from the nanowires such that the nanowires do not attain sufficiently high temperature to become vaporized. While decreasing the scanning speed or increasing the intensity of the continuous wave laser may allow the nanowires to absorb more energy per unit of time, this may cause damage to the base film upon which the transparent conductive film is disposed. However, it may be desirable to use continuous wave lasers since they may be less expensive than pulsed lasers. We have discovered that the use of a radiation absorbing substance may facilitate the use of a continuous wave laser, such as a laser diode. It is noted that a continuous wave laser may be used to deliver radiation in the form of pulses. When the modulation rate is on time scales much slower than the cavity lifetime and time period over which energy can be stored in the lasing medium, then it is still considered a continuous wave laser, that is, a “modulated” continuous wave laser.

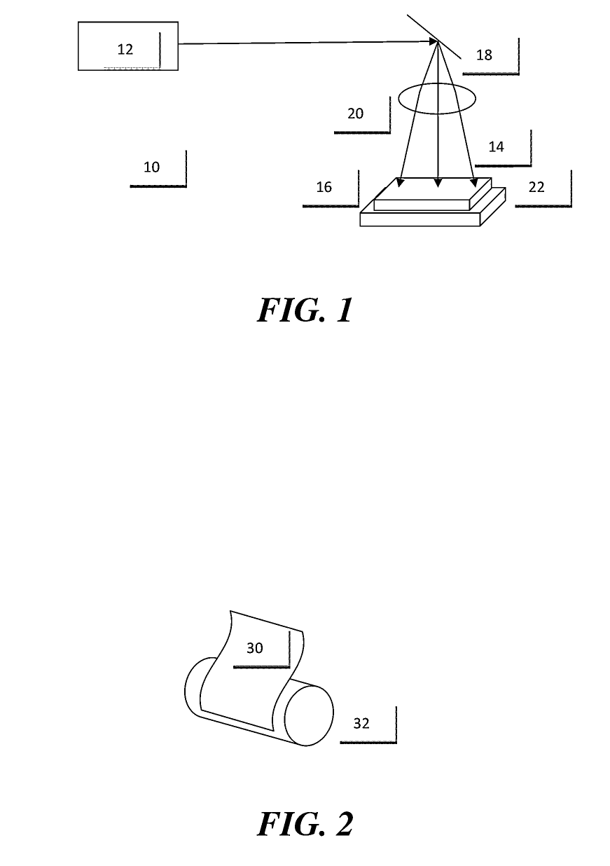

In some embodiments, a continuous wave laser, such as, for example, an infrared diode laser is used to apply infrared radiation. In the embodiment shown in FIG. 1, a laser apparatus 10 comprises a laser 12 that produces a laser beam 14 for patterning a transparent conductive film 16. In order to scan the laser beam 14 to provide relative movement between laser beam 14 and transparent conductive film 16, a scanning system 18 scans the laser beam 14 through a lens 20 to focus the scanned beam onto the transparent conductive film 16. The transparent conductive film 16 is moved by a transport system 22 allowing the full area of the film 16 to be scanned.

In some embodiments, a roll of film is patterned. In the embodiment shown in FIG. 2, a roll of transparent conductive film 30 is mounted on a rotating drum 32 for high throughput patterning. In some embodiments, more than one rotating drum is used. For example, a second rotating drum may receive patterned films.

In some embodiments, an infrared laser diode emits radiation having a wavelength in the range of 0.7 μm to 1000 μm. In some embodiments, an ultraviolet diode laser is used to pattern the transparent conductive film. In some embodiments, more than one laser is used simultaneously. In some embodiments, more than one scanning system is used. Scanning systems, such as, for example, a galvo-scanner or a polygon scanner, may be used. The scanning system may accomplish scanning by employing devices, such as, for example, moveable mirrors, rotating polygons with mirror faces, or rotating diffraction gratings. The lens may, in some cases, be an f-theta lens that focuses the scanned laser beam onto the transparent conductive film. The laser may be modulated. A continuous laser beam may be modulated by a separate module, such as an acoustic-optic modulator.

In some embodiments, a patterning kit may comprise at least one transparent conductive film comprising silver nanowires and a selected dye with an absorption peak at a wavelength and at least one laser diode that can emit radiation at that wavelength.

### EXEMPLARY EMBODIMENTS

U.S. Provisional Application No. 61/837,217, filed Jun. 20, 2013, entitled “LASER DIODE PATTERNING OF TRANSPARENT CONDUCTIVE FILMS,” which is hereby incorporated by reference in its entirety, disclosed the following 27 non-limiting exemplary embodiments:

A. A method for patterning a transparent conductive film comprising:

providing a transparent conductive film comprising a first region exhibiting a first resistivity, the first region comprising a metal nanowire and a radiation absorbing substance; and

irradiating the transparent conductive film with a radiation source,

wherein, after irradiation of the transparent conductive film, the first region exhibits a second resistivity that is higher than the first resistivity.

B. The method according to embodiment A, wherein the first region comprises a plurality of metal nanowires.
C. The method according to embodiment A, wherein the radiation absorbing substance comprises a bonding component.
D. The method according to embodiment C, wherein the bonding component comprises a ligand.
E. The method according to embodiment A, wherein the radiation source is a continuous wave laser.
F. The method according to embodiment A, wherein the radiation source is a diode.
G. The method according to embodiment A, wherein the radiation source is a laser diode.
H. The method according to embodiment A, wherein the radiation source emits ultraviolet radiation.
J. The method according to embodiment A, wherein the radiation source emits infrared radiation.
K. The method according to embodiment A, wherein the radiation absorbing substance exhibits an absorption peak at a wavelength, and the irradiating comprises irradiating the transparent conductive film with the laser diode emitting radiation at the wavelength.
L. The method according to embodiment A, wherein the irradiating comprises irradiating the first region, and further wherein the transparent conductive film comprises a second region exhibiting a third resistivity that is less than the second resistivity.
M. The method of according to embodiment A, wherein the metal nanowire comprises a silver nanowire.
N. The method according to embodiment A, wherein the radiation absorbing substance comprises an infrared absorbing substance.
P. The method according to embodiment A, wherein the radiation absorbing substance comprises an ultraviolet absorbing substance.
Q. The method according to embodiment A, wherein the radiation absorbing substance comprises a dye.
R. The method according to embodiment A, wherein the radiation absorbing substance exhibits one or more absorption peaks having a maximum at a wavelength from between about 0.7 to 1000 p.m.
S. The method according to embodiment A, wherein the radiation absorbing substance comprises 1,1′,3,3,3′,3′-hexamethylindotricarbocyanine iodide.
T. The method according to embodiment A, wherein the radiation absorbing substance comprises 3,3′-diethylthiatricarbocyanine perchlorate.
U. The method according to embodiment A, wherein the radiation absorbing substance comprises cyclobutenediylium, 1,3-bis[2,3-dihydro-2,2-bis[[(1-oxohexyl)oxy]methyl]-1H-perimidin-6-yl]-2,4-dihydroxy-bis(inner salt).
V. The method according to embodiment A, wherein the radiation absorbing substance comprises 6-chlor-2-[2-[3-[(6-chlor-1-ethyl-2H-benzo[cd]indol-2-yliden)-ethylidene]-2-phenyl-1-cyclopenten-1-yl]-ethenyl]-1-ethyl-benzo[cd]indolium tetrafluoroborate.
W. The method according to embodiment A, wherein the radiation absorbing substance comprises 4-[2-[2-chloro-3-[(2,6-diphenyl-4H-thiopyran-4-ylidene) ethylidene]-1-cyclohexen-1-yl]ethenyl]-2,6-diphenylthiopyrylium tetrafluoroborate.
X. The method according to embodiment A, wherein the radiation absorbing substance imparts no color that is visible to the unaided eye.
Y. A patterning kit comprising:

a transparent conductive film comprising a silver nanowire and a radiation absorbing substance, the radiation absorbing substance exhibiting an absorption peak at a wavelength; and,

a patterning device comprising a diode configured to irradiate the transparent conductive film at the wavelength.

Z. The patterning kit of embodiment Y, wherein the transparent conductive film comprises a plurality of silver nanowires.
AA. The patterning kit of embodiment Y, wherein the patterning device further comprises a scanning system.
AB. The patterning kit of embodiment Y, wherein the patterning device further comprises a film transport system.
AC. The patterning kit of embodiment AB, wherein the film transport system comprises a rotating drum configured to support the transparent conductive film.

### EXAMPLES

### Example 1

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using silver nanowire and each of the following infrared absorbing substances:

Dye 1: 1,1′,3,3,3′,3′-hexamethylindotricarbocyanine iodide (Sigma-Aldrich, Saint Louis)

Dye 2: 3,3′-diethylthiatricarbocyanine perchlorate (Sigma-Aldrich, Saint Louis)

Dye 3: cyclobutenediylium, 1,3-bis[2,3-dihydro-2,2-bis[[(1-oxohexyl)oxy]methyl]-1H-perimidin-6-yl]-2,4-dihydroxy-bis(inner salt) (H.W. Sands Corp., Jupiter, Fla.)

Dye 4: IR-1051 dye (Sigma-Aldrich, Saint Louis)

Dye 5: IR-1061 dye (Sigma-Aldrich, Saint Louis)

Control: No dye

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 2

### Prophetic

Each of the transparent conductive films formed from a different dye as discussed in Example 1 is irradiated with an infrared laser diode for a suitable duration. Each of the transparent conductive films formed from dyes 1, 2, 3, 4, and 5 are irradiated at wavelengths of 740 nm, 760 nm, 799 nm, 1051 nm, and 1061 nm, respectively. Portions of the control film are irradiated at wavelengths of 740 nm, 760 nm, 799 nm, 1051 nm, and 1061 nm. Each of the transparent conductive films is observed under scanning electron microscope. Resistivity measurements are taken of each of the transparent conductive films before and after irradiation.

### Example 3

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using silver nanowire and a suitable infrared dye with a ligand group that can or has the tendency to combine with or bind to the silver atom or ion of the silver nanowire at a first dye concentration level, a second dye concentration level, a third dye concentration level, a fourth dye concentration level, and a fifth dye concentration level. As a control, a transparent conductive film is made without any dye.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 4

### Prophetic

Each of the transparent conductive films formed from a different concentration of an infrared dye with ligand functionality as discussed in Example 3 is irradiated with an infrared laser diode for a suitable duration. Each of the transparent conductive films formed from different concentrations of the dye is irradiated at a wavelength at which the dye has an absorption peak. The control film is also irradiated at a wavelength at which the dye has an absorption peak. Each of the transparent conductive films is observed under scanning electron microscope. Resistivity measurements are taken of each of the transparent conductive films before and after irradiation.

### Example 5

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using silver nanowire and a suitable first ultraviolet dye, second ultraviolet dye, third ultraviolet dye, fourth ultraviolet dye, and fifth ultraviolet dye. A first ultraviolet dye is 2,6-diphenyl-4-(2,4,6-triphenyl-1-pyridinio)phenolate (Sigma-Aldrich, Saint Louis). A second ultraviolet dye is -chlor-2-[2-[3-[(6-chlor-1-ethyl-2H-benzo[cd]indol-2-yliden)-ethylidene]-2-phenyl-1-cyclopenten-1-yl]-ethenyl]-1-ethyl-benzo[cd]indolium tetrafluoroborate. As a control, a transparent conductive film is made without any dye.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 6

### Prophetic

Each of the transparent conductive films formed from a different ultraviolet dye as discussed in Example 5 is irradiated with an ultraviolet laser diode for a suitable duration. Each of the transparent conductive films formed from different ultraviolet dye are irradiated at a wavelength at which the dye has an absorption peak. The first ultraviolet dye is irradiated at 306 nm and 551 nm, and the second ultraviolet dye is irradiated at 531 nm. Portions of the control transparent conductive film made without any dye is irradiated at the wavelength at which the dye has an absorption peak. Each of the transparent conductive films is observed under scanning electron microscope. Resistivity measures are taken of each of the transparent conductive films before and after irradiation.

### Example 7

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using silver nanowire and a suitable ultraviolet dye with a ligand group that can or has a tendency to combine with or bind to a silver atom or ion of the silver nanowire at a first dye concentration level, a second dye concentration level, a third dye concentration level, a fourth dye concentration level, and a fifth dye concentration level. As a control, a transparent conductive film is made without any dye.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 8

### Prophetic

Each of the transparent conductive films formed from a different concentration of an ultraviolet dye with ligand functionality as discussed in Example 7 is irradiated with an ultraviolet laser diode for a suitable duration. Each of the transparent conductive films formed from different concentrations of the dye are irradiated at a wavelength at which the dye has an absorption peak. The control film is also irradiated at a wavelength at which the dye has an absorption peak. Each of the transparent conductive films is observed under scanning electron microscope. Resistivity measures are taken of each of the transparent conductive films before and after irradiation.

### Example 9

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using a suitable infrared dye without ligand functionality at a set dye concentration level and silver nanowire at a first concentration level, a second concentration level, a third concentration level, a fourth concentration level, and a fifth concentration level.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 10

### Prophetic

Each of the transparent conductive films formed from a different concentration of silver nanowire and a set concentration of an infrared dye without ligand functionality as discussed in Example 9 is irradiated with an infrared laser diode for a suitable duration. Each of the transparent conductive films formed from different concentrations of silver nanowire are irradiated at a wavelength at which the dye has an absorption peak. The control film is also irradiated at a wavelength at which the dye has an absorption peak. Each of the transparent conductive films is observed under scanning electron microscope. Resistivity measurements are taken of each of the transparent conductive films before and after irradiation.

### Example 11

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using a suitable infrared dye with a ligand component that can or has a tendency to combine with or bind to a silver atom or ion of the silver nanowire at a set dye concentration level and silver nanowire at a first concentration level, a second concentration level, a third concentration level, a fourth concentration level, and a fifth concentration level.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 12

### Prophetic

Each of the transparent conductive films formed from a different concentration of silver nanowire and a set concentration of an infrared dye with ligand functionality as discussed in Example 11 is irradiated with an infrared laser diode for a suitable duration. Each of the transparent conductive films formed from different concentrations of silver nanowire are irradiated at a wavelength at which the dye has an absorption peak. The control film is also irradiated at a wavelength at which the dye has an absorption peak. Each of the transparent conductive films is observed under scanning electron microscope. Resistivity measures are taken of each of the transparent conductive films before and after irradiation.

### Example 13

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using a suitable ultraviolet dye without ligand functionality at a set dye concentration level and silver nanowire at a first concentration level, a second concentration level, a third concentration level, a fourth concentration level, and a fifth concentration level.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples are tested for surface resistivity, % transmission, and adhesion to the support as described above.

### Example 14

### Prophetic

Each of the transparent conductive films formed from a different concentration of silver nanowire and a set concentration of an ultraviolet dye without ligand functionality as discussed in Example 13 is irradiated with an infrared laser diode for a suitable duration. Each of the transparent conductive films formed from different concentrations of silver nanowire are irradiated at a wavelength at which the dye has an absorption peak. The control film is also irradiated at a wavelength at which the dye has an absorption peak. Each of the transparent conductive films is observed under scanning electron microscope. Resistivity measures are taken of each of the transparent conductive films before and after irradiation.

### Example 15

### Prophetic

Preparation of transparent conductive film comprising silver nanowires is disclosed in U.S. patent application publication 2012/0107600, entitled “TRANSPARENT CONDUCTIVE FILM COMPRISING CELLULOSE ESTERS,” which is hereby incorporated by reference in its entirety. Several transparent conductive films are formulated using a suitable ultraviolet dye with a ligand group that can or has a tendency to combine with or bind to a silver atom or ion at a set dye concentration level and silver nanowire at a first concentration level, a second concentration level, a third concentration level, a fourth concentration level, and a fifth concentration level.

Each of the dispersions is mixed until homogeneous. The dispersion and an adhesion promoting composition are coated onto a substrate. The adhesion promoting coating is positioned as an intermediate layer between the dispersion coating and the substrate. The resulting dispersion coating is dried at suitable temperature for a suitable duration to obtain a dried transparent film.

Samples were tested for surface resistivity, % transmission, and adhesion to the support as described above.

### Example 16

### Prophetic

Each of the transparent conductive films formed from a different concentration of silver nanowire and a set concentration of an ultraviolet dye with ligand functionality as discussed in Example 15 is irradiated with an infrared laser diode for a suitable duration. Each of the transparent conductive films formed from different concentrations of silver nanowire are irradiated at a wavelength at which the dye has an absorption peak. The control film is also irradiated at a wavelength at which the dye has an absorption peak. Each of the transparent conductive films is observed under scanning electron microscope. Resistivity measures are taken of each of the transparent conductive films before and after irradiation.

The invention has been described in detail with reference to specific embodiments, but it will be understood that variations and modifications can be effected within the spirit and scope of the invention. The presently disclosed embodiments are therefore considered in all respects to be illustrative and not restrictive. The scope of the invention is indicated by the appended claims and all changes that come within the meaning and range of equivalents thereof are intended to be embraced therein.

What is claimed:

1. A method for patterning a transparent conductive film comprising:
providing a transparent conductive film comprising a first region exhibiting a first resistivity, the first region comprising a metal nanowire and a radiation absorbing substance; and
irradiating the transparent conductive film with a radiation source,
wherein, after irradiation of the transparent conductive film, the first region exhibits a second resistivity that is higher than the first resistivity.

2. The method according to claim 1, wherein the first region comprises a plurality of metal nanowires.

3. The method according to claim 1, wherein the radiation source is a laser diode.

4. The method according to claim 1, wherein the radiation source emits ultraviolet radiation.

5. The method according to claim 1, wherein the radiation source emits infrared radiation.

6. The method of according to claim 1, wherein the metal nanowire comprises a silver nanowire.

7. The method according to claim 1, wherein the radiation absorbing substance comprises an infrared absorbing substance.

8. The method according to claim 1, wherein the radiation absorbing substance comprises an ultraviolet absorbing substance.

9. The method according to claim 1, wherein the radiation absorbing substance comprises at least one of 1,1′,3,3,3′,3′-hexamethylindotricarbocyanine iodide; 3,3′-diethylthiatricarbocyanine perchlorate; cyclobutenediylium, 1,3-bis[2,3-dihydro-2,2-bis[[(1-oxohexyl)oxy]methyl]-1H-perimidin-6-yl]-2,4-dihydroxy-bis(inner salt); 6-chlor-2-[2-[3-[(6-chlor-1-ethyl-2H-benzo[cd]indol-2-yliden)-ethylidene]-2-phenyl-1-cyclopenten-1-yl]-ethenyl]-1-ethyl-benzo[cd]indolium tetrafluoroborate; or 4-[2-[2-chloro-3-[(2,6-diphenyl-4H-thiopyran-4-ylidene)ethylidene]-1-cyclohexen-1-yl]ethenyl]-2,6-diphenylthiopyrylium tetrafluoroborate.

10. The method according to claim 1, wherein the radiation absorbing substance imparts no color that is visible to the unaided eye.
